(19) United States
(12) Patent Application Publication
(10) Pub. No.: US 2025/0206341 A1
(43) Pub. Date: Jun. 26, 2025

(54) METHOD OF OPERATING INFORMATION PROCESSING APPARATUS, INFORMATION PROCESSING APPARATUS, AND MEDIUM

(71) Applicant: TOYOTA JIDOSHA KABUSHIKI KAISHA, Aichi-ken (JP)

(72) Inventors: Yuta EZOE, Taito-ku (JP); Shoya KOJIMA, Koto-ku (JP); Ryo TABA, Sumida-ku (JP); Harumichi HATTA, Nisshin-shi (JP); Ryota HORADA, Nisshin-shi (JP)

(21) Appl. No.: 18/988,646

(22) Filed: Dec. 19, 2024

(30) Foreign Application Priority Data
Dec. 20, 2023 (JP) 2023-215097

(51) Int. Cl. B60W 60/00; B60W 30/14

(52) U.S. Cl. CPC B60W 60/001; B60W 30/143; B60W 2530/201; B60W 2552/40; B60W 2554/4042; B60W 2554/4044; B60W 2554/80

(57) ABSTRACT

A method of operating an information processing apparatus includes operating in a plurality of pseudo situations by a mimic program that executes, according to a part of situations of a surrounding environment in which a vehicle travels, a part of control operation by a control program for controlling travel of the vehicle according to the situations, and extracting, from the plurality of pseudo situations, a first pseudo situation in which the vehicle and an object exhibit a predetermined state, for a simulation process by the control program. In the simulation process, the control operation by the control program is executed in the first pseudo situation.

### CROSS-REFERENCE TO RELATED APPLICATION

This application claims priority to Japanese Patent Application No. 2023-215097, filed on Dec. 20, 2023, the entire contents of which are incorporated herein by reference.

### TECHNICAL FIELD

The present disclosure relates to a method of operating an information processing apparatus, an information processing apparatus, and a medium.

### BACKGROUND

In the design phase of city blocks, technology for simulating traffic volume or the like by information processing apparatuses is known in order to study the possibility of traffic congestion or the like in the city blocks. For example, Patent Literature (PTL) 1 discloses a system for simulating an operation plan for public transportation vehicles.

### CITATION LIST

### Patent Literature

PTL 1: JP 2022-124910 A

### SUMMARY

In the simulation of vehicle operation in a city block, there are a variety of situations that can be assumed, such as the presence or absence of objects e.g., pedestrians and other vehicles in a travel route of a vehicle and movement states of the objects. Simulating the vehicle operation for each different situation requires enormous amounts of information processing and time. Therefore, it is desirable to reduce processing time while ensuring accuracy in the simulation.

The present disclosure provides a method of operating an information processing apparatus and the like that can reduce processing time while ensuring accuracy in the simulation of vehicle operation in a city block.

A method of operating an information processing apparatus according to the present disclosure includes:
operating in a plurality of pseudo situations by a mimic program that executes, according to a part of situations of a surrounding environment in which a vehicle travels, a part of control operation by a control program for controlling travel of the vehicle according to the situations; and
extracting, from the plurality of pseudo situations, a first pseudo situation in which the vehicle and an object exhibit a predetermined state, for a simulation process by the control program,
wherein in the simulation process, the control operation by the control program is executed in the first pseudo situation.

An information processing apparatus according to the present disclosure includes:
a memory configured to store a mimic program that executes, according to a part of situations of a surrounding environment in which a vehicle travels, a part of control operation by a control program for controlling travel of the vehicle according to the situations; and
a controller configured to:
   operate by the mimic program in a plurality of pseudo situations; and
   extract, from the plurality of pseudo situations, a first pseudo situation in which the vehicle and an object exhibit a predetermined state, for a simulation process by the control program,
wherein in the simulation process, the control operation by the control program is executed in the first pseudo situation.

In a non-transitory computer readable medium storing a program according to the present disclosure, the program is configured to cause an information processing apparatus to execute operations, the operations including:
operating in a plurality of pseudo situations by a mimic program that executes, according to a part of situations of a surrounding environment in which a vehicle travels, a part of control operation by a control program for controlling travel of the vehicle according to the situations; and
extracting, from the plurality of pseudo situations, a first pseudo situation in which the vehicle and an object exhibit a predetermined state, for a simulation process by the control program,
wherein in the simulation process, the control operation by the control program is executed in the first pseudo situation.

The method of operating an information processing apparatus and the like according to the present disclosure can reduce processing time while ensuring accuracy in the simulation of vehicle operation in a city block.

### BRIEF DESCRIPTION OF THE DRAWINGS

In the accompanying drawings:

FIG. 1 is a diagram illustrating an example of a configuration of an information processing system;

FIG. 2 is a diagram illustrating an example of information regarding simulation;

FIG. 3 is a flowchart illustrating an example of operations of a server apparatus;

FIG. 4 is a flowchart illustrating an example of operations of the server apparatus; and

FIG. 5 is a diagram that explains simple simulation.

### DETAILED DESCRIPTION

An embodiment will be described below.

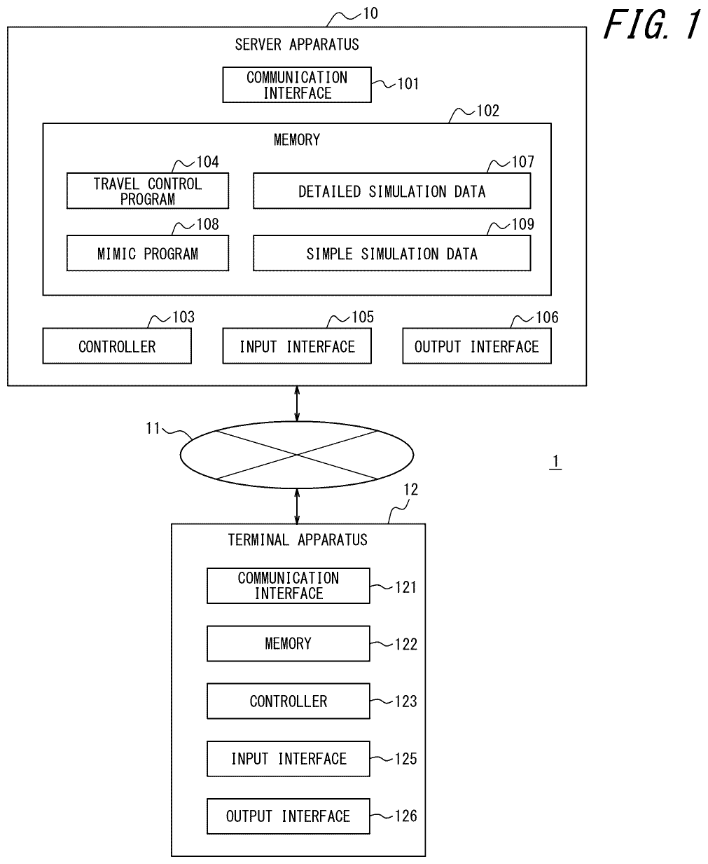

FIG. 1 is a diagram illustrating an example of a configuration of the embodiment of the present disclosure. An information processing system 1 includes a server apparatus 10 and a terminal apparatus 12 that are communicably connected to each other via a network 11 to communicate information. In the information processing system 1, the server apparatus 10 performs, in response to instructions transmitted from the terminal apparatus 12, information processing related to simulation in city block design. The terminal apparatus 12 is, for example, one or more information processing apparatuses such as personal computers or tablet terminal apparatuses. The information processing apparatuses may include smartphones or other devices. The server apparatus 10 is, for example, one or more server computers. The server apparatus 10 may be a single server computer, or may be multiple server computers that execute operations in the present embodiment in conjunction with each other and provide services. The network 11 may be, for example, a local area network (LAN), the Internet, an ad hoc network, a metropolitan area network (MAN), a mobile communication network, other networks, or any combination thereof.

The server apparatus 10, which corresponds to an “information processing apparatus” according to the present embodiment, executes the information processing for the simulation in the city block design upon receiving the instructions from the terminal apparatus 12. The simulation is, for example, the virtual simulation of travel of a vehicle operated on streets in a city block in a so-called smart city or the like, under various situations. The vehicle is, for example, a commercial vehicle, such as a bus or a truck, the driving of which is automated at any level, such as one of Level 1 to Level 5 defined by the Society of Automotive Engineers (SAE). The various situations (hereinafter referred to as “surrounding situations”) include movement patterns of objects such as pedestrians, bicycles, and other vehicles that intersect a travel route of the vehicle, states of blind spots from the vehicle on the streets, and the like. In the simulation, the vehicle is virtually operated based on control operation that is executed according to the surrounding situations by a travel control program installed in the vehicle. In the present embodiment, the simulation is executed in two stages. In other words, a method of operating the server apparatus 10 includes a simple simulation process that operates in a plurality of pseudo surrounding situations by a mimic program that executes, according to a part of the surrounding situations of a surrounding environment in which the vehicle travels, a part of the control operation by the travel control program for controlling the travel of the vehicle according to the surrounding situations, and a selection process that extracts, from the plurality of pseudo surrounding situations, one or more pseudo surrounding situations in which the vehicle and an object exhibit a predetermined state, for a detailed simulation process by the travel control program. In the detailed simulation process, the control operation by the travel control program is executed in the pseudo surrounding situations (hereinafter referred to as “sample surrounding situations”) extracted in the selection process.

According to the present embodiment, as a result of the simple simulation process by the mimic program, which limitedly simulates the control operation by the travel control program and hence has a smaller processing load than the travel control program, the sample surrounding situations, in which the vehicle and the object exhibit the predetermined state, e.g., the closest approach distance between the vehicle and the object is less than a reference distance, are extracted. Then, the detailed simulation process by the travel control program is executed in the sample surrounding situations. By executing the simple simulation process by the mimic program based on the travel control program, the sample surrounding situations can be extracted while accuracy in the simulation is maintained in some degree. By executing the detailed simulation process for the sample surrounding situations, the simulation can be executed with a smaller overall processing load than when detailed simulation is executed for all the pseudo surrounding situations. Therefore, it is possible to reduce processing time while ensuring accuracy in the simulation of vehicle operation in the city block.

Next, configurations of the server apparatus 10 and the terminal apparatus 12 will be described.

The server apparatus 10 includes a communication interface 101, a memory 102, a controller 103, an input interface 105, and an output interface 106. When the server apparatus 10 is configured with two or more server computers, these components are appropriately arranged in the two or more server computers.

The communication interface 101 includes one or more interfaces for communication. The interface for communication is, for example, a LAN interface. The communication interface 101 receives information to be used for operations of the server apparatus 10 and transmits information obtained by the operations of the server apparatus 10. The server apparatus 10 is connected to the network 11 by the communication interface 101 and communicates information with the terminal apparatus 12 via the network 11.

The memory 102 includes, for example, one or more semiconductor memories, one or more magnetic memories, one or more optical memories, or a combination of at least two of these types, to function as main memory, auxiliary memory, or cache memory. The semiconductor memory is, for example, Random Access Memory (RAM) or Read Only Memory (ROM). The RAM is, for example, Static RAM (SRAM) or Dynamic RAM (DRAM). The ROM is, for example, Electrically Erasable Programmable ROM (EEPROM). The memory 102 stores information to be used for operations of the controller 103 and information obtained by the operations of the controller 103. The memory 102 stores, for example, a travel control program 104 and detailed simulation data 107 for the detailed simulation process, and a mimic program 108 and simple simulation data 109 for the simple simulation process.

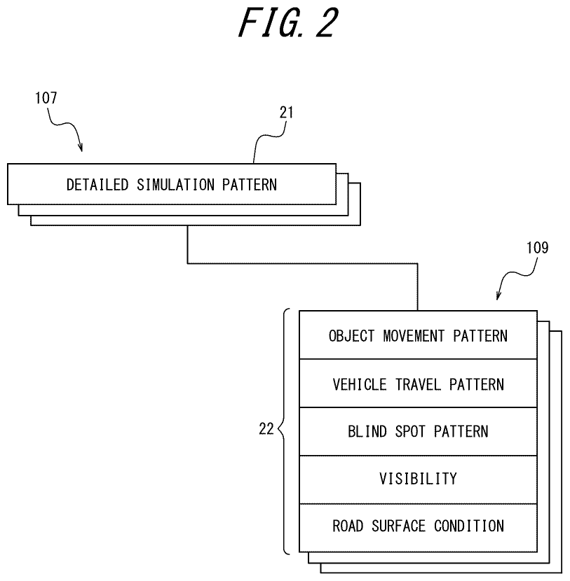

FIG. 2 is a diagram illustrating the detailed simulation data 107 for the detailed simulation process and the simple simulation data 109 for the simple simulation process. The detailed simulation data 107 includes data for multiple simulation patterns 21. Data for each simulation pattern 21 is data corresponding to the pseudo surrounding situation that is equivalent to data detected by sensors of the vehicle when the vehicle travels through the city block. The data for the multiple simulation patterns 21 are data representing the surrounding situations different from each other. The data for the multiple simulation patterns 21 include, for example, data such as images captured by cameras of the vehicle, vehicle conditions, and motion states of the vehicle. The captured images include objects, obstacles, and the like around the vehicle. The vehicle conditions include body vibration, temperature, and the like. The motion states of the vehicle include a vehicle speed, an acceleration and deceleration, and the like. The data for the simulation patterns 21 may be data detected and collected by the sensors when the vehicle actually travels through the city block, or may be data created for the detailed simulation in a format of actual detection data. The simple simulation data 109 includes data for multiple simulation patterns 22. Data for each simulation pattern 22 is data representing a part of the surrounding situations when the vehicle travels through the city block, and corresponds to data representing a part of the pseudo surrounding situations. The data for the simulation patterns 22 includes, for example, data on object movement patterns, vehicle travel patterns, blind spot patterns, visibility, road surface conditions, and the like. The object movement patterns include movement routes, movement speeds, accelerations and decelerations, and the like of the objects. The vehicle travel patterns include a travel route, a vehicle speed, an acceleration and deceleration, and the like of the vehicle. The blind spot patterns include locations, extents, and the like of blind spots around the vehicle. The visibility includes areas that can be captured by the cameras of the vehicle. The road surface conditions include the amount of friction on a road surface when the vehicle is braking. The data for the simulation patterns 22 is data created for the simple simulation, and does not necessarily have to be in the format of the detection data by the sensors of the vehicle. The data for the simulation patterns 22 is in correspondence with the data for the simulation patterns 21 of the detailed simulation data 107 including the corresponding surrounding situations. Information on the correspondence between the data for the simulation patterns 21 and the data for the simulation patterns 22 is stored in the memory 102.

Returning to FIG. 1, the controller 103 includes one or more processors, one or more dedicated circuits, or a combination thereof. The processor is a general purpose processor, such as a central processing unit (CPU), or a dedicated processor, such as a graphics processing unit (GPU), specialized for a particular process. The dedicated circuit is, for example, a field-programmable gate array (FPGA), an application specific integrated circuit (ASIC), or the like. The controller 103 executes information processing related to the operations of the server apparatus 10 while controlling the components of the server apparatus 10.

The functions of the server apparatus 10 are realized by a processor included in the controller 103 executing a control program. The control program is a program for causing the processor to function as the controller 103. Some or all of the functions of the server apparatus 10 may be realized by a dedicated circuit included in the controller 103. The control program may be stored on a non-transitory recording/storage medium readable by the controller 103, and be read from the medium by the controller 103.

The controller 103 executes the simple simulation process using the simple simulation data 109 by executing the mimic program 108. The controller 103 also simulates, by executing an emulation program, for example, an operating environment of a control apparatus such as an electronic control unit (ECU) in which the travel control program 104 is implemented in the vehicle. The controller 103 then executes the detailed simulation process using the detailed simulation data 107 by executing the travel control program 104 in the simulated operating environment.

The input interface 105 includes one or more interfaces for input. The interface for input is, for example, a physical key, a capacitive key, a pointing device, a touch screen integrally provided with a display, or a microphone that receives audio input. The input interface 105 accepts operations for inputting information to be used in the operations of the server apparatus 10 and transmits the inputted information to the controller 103.

The output interface 106 includes one or more interfaces for output. The interface for output is, for example, a display or a speaker. The display is, for example, a liquid crystal display (LCD) or an organic electro-luminescence (EL) display. The output interface 106 outputs information obtained by the operations of the server apparatus 10.

The terminal apparatus 12 includes a communication interface 121, a memory 122, a controller 123, an input interface 125, and an output interface 126.

The communication interface 121 includes a communication module compliant with a wired or wireless LAN standard, a module compliant with a mobile communication standard such as LTE, 4G, or 5G, or the like. The terminal apparatus 12 connects, by the communication interface 121, to the network 11 via a nearby router apparatus or mobile communication base station, and communicates information with the server apparatus 10 and the like over the network 11.

The memory 122 includes, for example, one or more semiconductor memories, one or more magnetic memories, one or more optical memories, or a combination of at least two of these types. The semiconductor memory is, for example, RAM or ROM. The RAM is, for example, SRAM or DRAM. The ROM is, for example, EEPROM. The memory 122 functions as, for example, a main memory, an auxiliary memory, or a cache memory. The memory 122 stores information to be used for operations of the controller 123 and information obtained by the operations of the controller 123.

The controller 123 has one or more general purpose processors, such as CPUs or micro processing units (MPUs), or one or more dedicated processors, such as GPUs, that are dedicated to specific processing. Alternatively, the controller 123 may have one or more dedicated circuits such as FPGAs or ASICs. The controller 123 is configured to perform overall control of operations of the terminal apparatus 12 by operating according to control/processing programs or operating according to operating procedures implemented in the form of circuits. The controller 123 then transmits and receives various types of information to and from the server apparatus 10 and the like via the communication interface 121, to execute operations according to the present embodiment.

The functions of the terminal apparatus 12 are realized by a processor included in the controller 123 executing a control program. The control program is a program for causing the processor to function as the controller 123. Some or all of the functions of the terminal apparatus 12 may be realized by a dedicated circuit included in the controller 123. The control program may be stored on a non-transitory recording/storage medium readable by the controller 123 and be read from the medium by the controller 123.

The input interface 125 includes one or more interfaces for input. The interface for input may include, for example, a physical key, a capacitive key, a pointing device, and a touch screen integrally provided with a display. The interface for input may also include a microphone that accepts audio input and a camera that captures images. The interface for input may further include a scanner, camera, or IC card reader that scans an image code. The input interface 125 accepts operations for inputting information to be used in the operations of the controller 123 and transmits the inputted information to the controller 123. The input interface 125 transmits, to the controller 123, the images captured by the camera.

The output interface 126 includes one or more interfaces for output. The interface for output may include, for example, a display and a speaker. The display is, for example, an LCD or an organic EL display. The output interface 126 outputs information obtained by the operations of the controller 123.

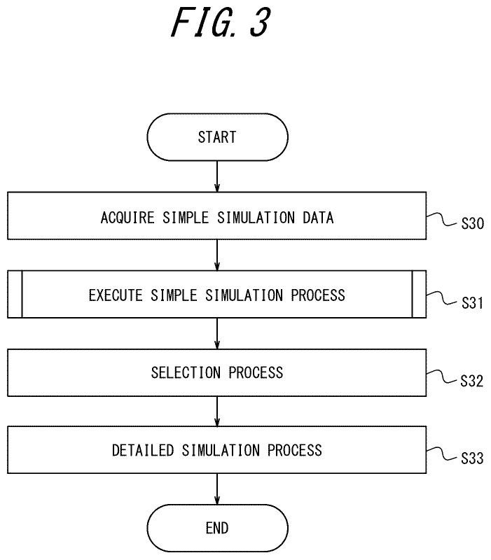

FIG. 3 is a flowchart illustrating an example of the operations of the server apparatus 10 according to the present embodiment. Each step is executed by the controller 103. A procedure in FIG. 3 is executed, for example, by receiving the instructions from the terminal apparatus 12 operated by an operator.

In step S30, the controller 103 acquires simple simulation data. The controller 103 reads and acquires the simple simulation data 109, which is stored in advance in the memory 102. Alternatively, the operator inputs any simple simulation data using the input interface 125 of the terminal apparatus 12, and the controller 123 of the terminal apparatus 12 transmits, by the communication interface 121, the input data to the server apparatus 10. The controller 103 of the server apparatus 10 receives, by the communication interface 101, the information transmitted from the terminal apparatus 12. The controller 103 thereby acquires the simple simulation data. Alternatively, the operator may input any simple simulation data using the input interface 105 of the server apparatus 10, and the controller 103 may acquire the input simple simulation data.

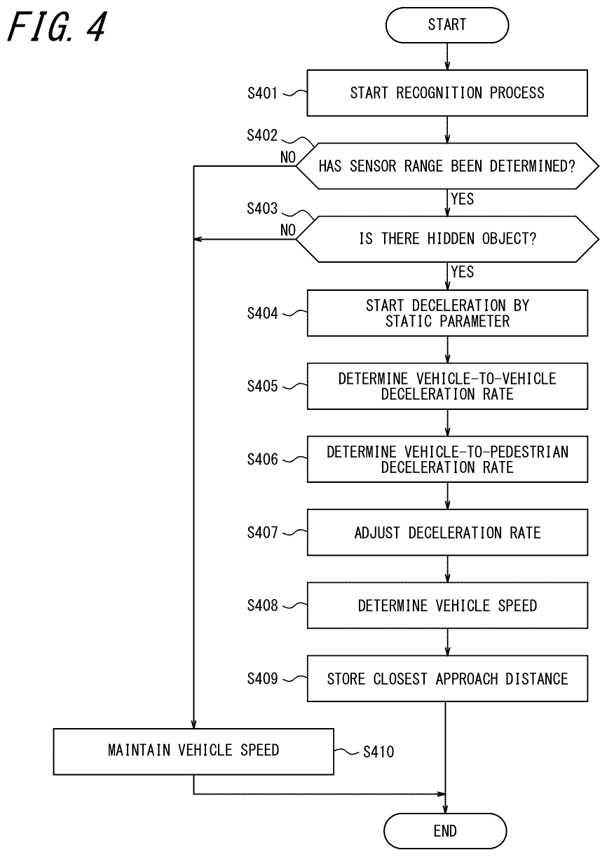

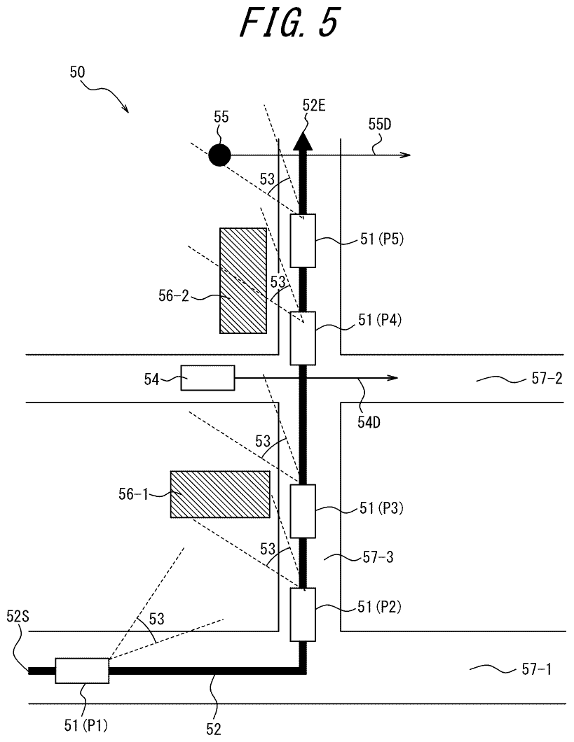

In step S31, the controller 103 executes the simple simulation process. The operator inputs instructions for execution of the simple simulation process using the input interface 125 of the terminal apparatus 12. The controller 123 of the terminal apparatus 12 transmits, by the communication interface 121, the input instructions to the server apparatus 10. The controller 103 of the server apparatus 10 receives, by the communication interface 101, the instructions transmitted from the terminal apparatus 12. The controller 103 thereby executes, according to the mimic program 108, the simple simulation process using the simple simulation data. Details on the simple simulation process are illustrated in FIGS. 4 and 5.

FIG. 4 is a flowchart illustrating an example of an operation procedure of the server apparatus 10 executing the simple simulation process. Each step in FIG. 4 is a step defined by the mimic program 108. FIG. 5 is also a diagram schematically illustrating an example of the simple simulation defined by the mimic program 108. As illustrated in FIG. 5, the simple simulation is performed to simulate, when a vehicle 51 (P1 to P5 in parentheses indicate positions over time) travels along a travel route 52 from a start point 52S to an end point 52E on streets 57-1 and 57-3 in a city block 50, the closest approach distance between the vehicle 51 and another vehicle 54 or a pedestrian 55 that moves across the travel route 52. Here, the arrangement of streets 57-1 to 57-3 in the city block 50 is defined by the mimic program 108. Surrounding situations, including travel patterns of the vehicle 51, movement patterns of objects such as the other vehicle 54 and the pedestrian 55, and the locations, dimensions, shapes, and the like of obstacles 56-1, 56-2, and the like, are defined by the data for the simulation patterns 22 so as to be different for each simulation pattern 22. For example, as the movement pattern of the object such as the other vehicle 54 or the pedestrian 55, a movement route, a movement speed, an acceleration and deceleration, and the like of the object are defined. In addition, as the travel pattern of the vehicle 51, a travel route, a vehicle speed, an acceleration and deceleration, and the like of the vehicle 51 are defined. Furthermore, as a blind spot pattern, the locations, ranges, and the like of blind spots around the vehicle 51 are defined by the locations, dimensions, shapes, and the like of the obstacles 56-1, 56-2, and the like. Furthermore, the field of view 53 of a camera of the vehicle 51 is defined by variations in visibility. For example, the range of the field of view 53 is set to be relatively small in a variation that assumes a relatively low amount of light, such as during cloudy weather or at night.

In step S401 in FIG. 4, the controller 103 starts a recognition process. The recognition process is, for example, a process of capturing the object in the field of view 53 of the camera of the vehicle 51.

In step S402, the controller 103 determines whether a sensor range has been determined. The sensor range is, for example, the field of view 53 of the camera. When the field of view 53 is set to a range corresponding to the position of the vehicle 51 in the city block 50, it can be determined that the sensor range has been determined (Yes in step S402), and the controller 103 proceeds to step S403. When it is determined that the sensor range has not been determined (No in step S402), the controller 103 proceeds to step S410, determines to maintain the vehicle speed of the vehicle 51, and ends the procedure in FIG. 4.

In step S403, the controller 103 determines whether there is a hidden object. For example, since the field of view 53 of the vehicle 51 at positions P1, P3 and P5 does not include the obstacles 56-1 and 56-2, it is determined that there is no hidden object. Since the field of view 53 of the vehicle 51 at positions P2 and P4 includes the obstacles 56-1 and 56-2, respectively, it is determined that there is a hidden object. When it is determined that there is a hidden object (Yes in step S403), the controller 103 proceeds to step S404. When it is determined that there is no hidden object (No in step S403), the controller 103 proceeds to step S410, determines to maintain the vehicle speed of the vehicle 51, and ends the procedure in FIG. 4.

In step S404, the controller 103 starts decelerating the vehicle 51 by a static parameter. The static parameter is any value defined in advance in the mimic program 108, and corresponds to a deceleration rate for preliminary deceleration of the vehicle 51.

In step S405, the controller 103 determines a vehicle-to-vehicle deceleration rate. For example, as the vehicle 51 travels to the position P3, the other vehicle 54 that travels along a direction 54D on the street 57-2, which intersects the street 57-3, is captured in the field of view 53. The controller 103, for example, derives, based on a variation in the position of the other vehicle 54 with time, the time until the other vehicle 54 intersects the travel route 52, and determines the deceleration rate to avoid contact with the other vehicle 54. Alternatively, when the other vehicle 54 is not included in the field of view 53 or when the time until the other vehicle 54 intersects the travel route 52 is longer than an arbitrary criterion, the controller 103 may maintain the vehicle speed of vehicle 51. The arbitrary criterion is set equal to or more than the time required for the vehicle 51 to reach a point at which the other vehicle 54 intersects the travel route 52.

In step S406, the controller 103 determines a vehicle-to-pedestrian deceleration rate. For example, as the vehicle 51 travels to the position P5, the pedestrian 55 that moves along a direction 55D across the street 57-3 is captured in the field of view 53. The controller 103, for example, derives, based on a variation in the position of the pedestrian 55 with time, the time until the pedestrian 55 intersects the travel route 52, and determines the deceleration rate to avoid contact with the pedestrian 55. Alternatively, when the pedestrian 55 is not included in the field of view 53 or when the time until the pedestrian 55 intersects the travel route 52 is longer than an arbitrary criterion, the controller 103 may maintain the vehicle speed of vehicle 51. The arbitrary criterion is set equal to or more than the time required for the vehicle 51 to reach a point at which the pedestrian 55 intersects the travel route 52.

In step S407, the controller 103 adjusts the deceleration rate. For example, the controller 103 adjusts the deceleration rate to a value equal to or less than a maximum deceleration rate that is possible under specifications of the vehicle 51.

In step S408, the controller 103 determines the vehicle speed. For example, the controller 103 determines the vehicle speed of the decelerated vehicle 51 by deceleration with the adjusted deceleration rate. This executes simulation in which the vehicle 51 travels at the decelerated vehicle speed. In such simple simulation, the controller 103 may generate computer graphics (CG) images representing the city block 50, the vehicle 51, the other vehicle 54, the pedestrian 55, the obstacles 56-1 and 56-2, and the like, and transmit the CG images to the terminal apparatus 12. Thus, the operator can view the CG images of the simple simulation with the terminal apparatus 12.

In step S409, the controller 103 stores the closest approach distance between the vehicle 51 and the object. For example, when the vehicle 51 travels at the decelerated vehicle speed, the controller 103 derives the distance of closest approach between the vehicle 51 and the other vehicle 54 or pedestrian 55, and stores the distance of closest approach in the memory 102, together with identification information on the data for the simulation pattern 22. The closest approach includes a case in which the vehicle 51 makes contact with the other vehicle 54 or pedestrian 55.

Returning to FIG. 3, in step S32, the controller 103 executes the selection process. The controller 103 executes the selection process according to the mimic program 108. As a result of the simple simulation, the controller 103 extracts, from the plurality of pseudo surrounding situations, one or more pseudo surrounding situations in which the vehicle and the object exhibit a predetermined state, for the detailed simulation process by the travel control program. For example, the controller 103 extracts data for simulation patterns 22 in which the closest approach distance between the vehicle and the object is equal to or less than an arbitrary criterion. The criterion for the closest approach distance is a value arbitrarily determined in a range of tens of centimeters to two meters, for example, such that the probability of a contact accident is greater than a certain degree. When deriving the closest approach distance between the vehicle 51 and the object, the controller 103 may, for example, derive the closest approach distance by taking into account the object movement pattern, such as the movement route, the movement speed, the acceleration and deceleration, and the like of the object, using any algorithm. The controller 103 may also derive the closest approach distance by taking into account variations in the travel pattern of the vehicle 51, such as the travel route, the vehicle speed, the acceleration and deceleration, and the like of the vehicle 51, using any algorithm. In addition, the controller 103 may derive the closest approach distance by adjusting a braking distance when the vehicle 51 decelerates, taking into account the road surface conditions using any algorithm. Alternatively, the controller 103 may extract data for any number of simulation patterns 22 in order of increasing the closest approach distance between the vehicle and the object. In other words, any top number of pseudo surrounding situations in which the closest approach distance between the vehicle and the object is in increasing order are extracted. The controller 103 stores, in the memory 102, identification information on data for simulation patterns 21 corresponding to the data for the extracted simulation patterns 22. Here, the data for the simulation patterns 21 corresponding to the data for the extracted simulation patterns 22 corresponds to the sample surrounding situations.

In step S33, the controller 103 executes the detailed simulation process. The operator inputs instructions for execution of the detailed simulation process using the input interface 125 of the terminal apparatus 12. The controller 123 of the terminal apparatus 12 transmits, by the communication interface 121, the input instructions to the server apparatus 10. The controller 103 of the server apparatus 10 receives, by the communication interface 101, the instructions transmitted from the terminal apparatus 12. The controller 103 thereby executes the detailed simulation process using the detailed simulation data 107 according to the travel control program 104. At this time, the controller 103 executes the detailed simulation using the data for the simulation patterns 21 extracted by the selection process. The controller 103 outputs signals, data, and the like similar to those output by the ECU, for example, according to the detailed simulation data 107, by emulating the implementation environment of the travel control program 104 in the vehicle and executing the travel control program 104. Furthermore, the controller 103 extracts data for one or more simulation patterns 21 in which the closest approach distance between the vehicle and the object is equal to or less than an arbitrary criterion. The criterion for the closest approach distance is a value arbitrarily determined in a range of tens of centimeters to two meters, for example, such that the probability of a contact accident is greater than a certain degree. In the detailed simulation process, the controller 103 may generate CG images that represent pseudo surrounding environments corresponding to the data for the simulation patterns 21 and operation of the vehicle 51 corresponding to output obtained by executing the travel control program 104, and transmits the CG images to the terminal apparatus 12. Thus, the operator can view the CG images of the detailed simulation with the terminal apparatus 12.

According to the present embodiment, by executing the simple simulation process by the mimic program based on the travel control program, the sample surrounding situations can be extracted while accuracy in the simulation is maintained in some degree. By executing the detailed simulation process for the sample surrounding situations, the simulation can be executed with a smaller overall processing load than when detailed simulation is executed for all the surrounding situations. Specifically, by excluding, from screening, phenomena that are outside a recognition range of the vehicle, it is possible to execute the detailed simulation concentrating on events that are caused by the difficulty of recognition from the vehicle due to the infrastructure of the city block. Therefore, it is possible to reduce processing time while ensuring accuracy in the simulation of the vehicle operation in the city block.

In the present embodiment, the simple simulation process, the selection process, and the detailed simulation process may be distributed and executed by two or more server computers. The present embodiment includes a case in which the above procedure described as the operations of the server apparatus 10 is executed by an information processing apparatus, such as a stand-alone PC, for example. Furthermore, an information processing apparatus such as a server computer or PC may be configured communicably with the ECU or equivalent control apparatus installed in the vehicle, and emulate the operating environment of the detailed simulation by the configuration with the ECU or the like.

While the embodiment has been described with reference to the drawings and examples, it should be noted that various modifications and revisions may be implemented by those skilled in the art based on the present disclosure. Accordingly, such modifications and revisions are included within the scope of the present disclosure. For example, functions or the like included in each means, each step, or the like can be rearranged without logical inconsistency, and a plurality of means, steps, or the like can be combined into one or divided.

1. A method of operating an information processing apparatus, the method comprising:
operating in a plurality of pseudo situations by a mimic program that executes, according to a part of situations of a surrounding environment in which a vehicle travels, a part of control operation by a control program for controlling travel of the vehicle according to the situations; and
extracting, from the plurality of pseudo situations, a first pseudo situation in which the vehicle and an object exhibit a predetermined state, for a simulation process by the control program,
wherein in the simulation process, the control operation by the control program is executed in the first pseudo situation.

2. The method according to claim 1, wherein the part of the situations includes a movement speed of the object, an acceleration and deceleration of the object, a movement route of the object, a blind spot location of the vehicle, a dimension of the vehicle, and/or a shape of the vehicle.

3. The method according to claim 2, wherein the part of the situations further includes visibility and/or a road surface condition.

4. The method according to claim 1, wherein the part of the control operation is acceleration and deceleration of the vehicle on a predetermined travel route.

5. The method according to claim 1, wherein the predetermined state is that a closest approach distance between the vehicle and the object satisfies a first criterion.

6. The method according to claim 1, further comprising the simulation process.

7. The method according to claim 6, wherein in the simulation process, whether a closest approach distance between the vehicle and the object satisfies a second criterion is determined.

8. An information processing apparatus comprising:
a memory configured to store a mimic program that executes, according to a part of situations of a surrounding environment in which a vehicle travels, a part of control operation by a control program for controlling travel of the vehicle according to the situations; and
a controller configured to:
operate by the mimic program in a plurality of pseudo situations; and
extract, from the plurality of pseudo situations, a first pseudo situation in which the vehicle and an object exhibit a predetermined state, for a simulation process by the control program,
wherein in the simulation process, the control operation by the control program is executed in the first pseudo situation.

9. The information processing apparatus according to claim 8, wherein the part of the situations includes a movement speed of the object, an acceleration and deceleration of the object, a movement route of the object, a blind spot location of the vehicle, a dimension of the vehicle, and/or a shape of the vehicle.

10. The information processing apparatus according to claim 9, wherein the part of the situations further includes visibility and/or a road surface condition.

11. The information processing apparatus according to claim 8, wherein the part of the control operation is acceleration and deceleration of the vehicle on a predetermined travel route.

12. The information processing apparatus according to claim 8, wherein the predetermined state is that a closest approach distance between the vehicle and the object satisfies a first criterion.

13. The information processing apparatus according to claim 8, wherein the controller is configured to further execute the simulation process.

14. The information processing apparatus according to claim 13, wherein the controller is configured to determine, in the simulation process, whether a closest approach distance between the vehicle and the object satisfies a second criterion.

15. A non-transitory computer readable medium storing a program configured to cause an information processing apparatus to execute operations, the operations comprising:
operating in a plurality of pseudo situations by a mimic program that executes, according to a part of situations of a surrounding environment in which a vehicle travels, a part of control operation by a control program for controlling travel of the vehicle according to the situations; and
extracting, from the plurality of pseudo situations, a first pseudo situation in which the vehicle and an object exhibit a predetermined state, for a simulation process by the control program,
wherein in the simulation process, the control operation by the control program is executed in the first pseudo situation.

16. The non-transitory computer readable medium according to claim 15, wherein the part of the situations includes a movement speed of the object, an acceleration and deceleration of the object, a movement route of the object, a blind spot location of the vehicle, a dimension of the vehicle, and/or a shape of the vehicle.

17. The non-transitory computer readable medium according to claim 16, wherein the part of the situations further includes visibility and/or a road surface condition.

18. The non-transitory computer readable medium according to claim 15, wherein the part of the control operation is acceleration and deceleration of the vehicle on a predetermined travel route.

19. The non-transitory computer readable medium according to claim 15, wherein the predetermined state is that a closest approach distance between the vehicle and the object satisfies a first criterion.

20. The non-transitory computer readable medium according to claim 15, wherein the program is configured to cause the information processing apparatus to further execute the simulation process.
